(19) United States
(12) Patent Application Publication
(10) Pub. No.: US 2024/0332402 A1
(43) Pub. Date: Oct. 3, 2024

(54) METHOD FOR MANUFACTURING SUPERJUNCTION TRENCH GATE MOSFET

(71) Applicant: Hua Hong Semiconductor (Wuxi) Limited, Wuxi (CN)

(72) Inventor: Zhaozhao XU, Wuxi (CN)

(21) Appl. No.: 18/545,228

(22) Filed: Dec. 19, 2023

(30) Foreign Application Priority Data
Mar. 29, 2023 (CN) 202310315942.8

(51) Int. Cl. H01L 29/66; H01L 21/24; H01L 21/265; H01L 21/266; H01L 21/285; H01L 21/3213; H01L 29/06; H01L 29/45; H01L 29/78

(52) U.S. Cl. CPC H01L 29/66734; H01L 21/244; H01L 21/26513; H01L 21/266; H01L 21/28568; H01L 21/32134; H01L 21/32139; H01L 29/0634; H01L 29/45; H01L 29/7813

(57) ABSTRACT

The present application discloses a method for manufacturing a superjunction trench gate MOSFET, wherein after a top metal layer is fully etched off using a photomask for etching the top metal layer and a second mask layer, the second mask layer is not removed. Etching continues on exposed metal tungsten in a source region source contact to fully etch off the exposed metal tungsten in the source region source contact, followed by removing the second mask layer, and then a second dielectric layer is formed, not only reducing mask layers to reduce manufacturing costs, but also avoiding short circuits caused by connection of the exposed metal tungsten in the source region source contact to other conductors. The exposure of metal tungsten can be avoided in the case of saving one mask layer, and the process risk is reduced.

### CROSS-REFERENCES TO RELATED APPLICATIONS

This application claims priority to Chinese Patent Application No. 202310315942.8, filed on Mar. 29, 2023, the disclosure of which is incorporated herein by reference in its entirety.

### TECHNICAL FIELD

The present application pertains to integrated circuit design and manufacturing technologies, and particularly relates to a method for manufacturing a superjunction trench gate MOSFET.

### BACKGROUND

Trench gate MOSFET devices are widely used in power conversion circuits and commonly used as power switch devices. An on-resistance Rsp and a breakdown voltage BV are important ones among parameter indexes of a trench gate. The acquisition of a higher breakdown voltage BV and a lower on-resistance Rsp can improve the product competitiveness. In order to improve the on-resistance of medium and high voltage (50-200 V) trench gates, the concept of a superjunction trench gate realized by implantation is proposed. Referring to FIG. 1, a source doped pillar (P-pillar/PPL) 1032 is formed in an epitaxial layer below a bulk region between trench gates to assist in the depletion of an N-type drift region, and a bottom end of the source doped pillar (P-pillar/PPL) 1032 is as close as possible to a highly doped N-type substrate 101 to make a depletable N-type drift region longer.

For design simplification, during implantation for the source doped pillar (P-pillar/PPL) 1032, an additional mask layer is introduced as the PPL implantation, referring to FIG. 2. However, the introduction of the additional mask layer increases manufacturing costs of the process, thereby declining advantages of the superjunction.

A section along a cut line B in FIG. 2 is shown in FIG. 1, and a section along a cut line A is shown in FIG. 3, where a gate end is led through a contact (CT) 109 to a gate region metal layer GATE M1 along the cut line A, and a source-bulk region end is led through the contact (CT) 109 to a source-bulk region metal layer SOURCE-BULK M1 along the cut line B. This design pattern enables the process to lead the gate end and the source-bulk end separately using only one metal layer, that is, a top metal layer M1 is divided into the gate region metal layer (GATE M1, GATE PAD M1) and the source-bulk region metal layer (SOURCE-BULK M1, SOURCE M1). In order to reduce a chip area, due to the coexistence of the contact (CT) and the doped pillar mask layer (PPL layer), in FIG. 2, the gate region metal layer (GATE M1) on the left side and a portion of the intermediate gate pad metal layer (GATE PAD M1) may be placed at a middle position along an anterior-posterior direction of the annular source doped pillar (P-pillar/PPL) 1032 and an annular trench gate 105 of a terminal.

Reducing the mask layer is the most direct and effective way to further reduce manufacturing costs of a superjunction trench gate MOSFET.

An existing method for manufacturing an N-type superjunction trench gate MOSFET includes the following steps:
(I) forming a trench gate 105 in an N-type epitaxial layer 102 on an upper side of an N-type substrate 101, forming a P-type bulk region 106 in a surface layer of the N-type epitaxial layer 102, and performing N-type heavy doping implantation in the surface layer of the P-type bulk region 106 to form a source end N-type implantation region 108;
(II) forming a first dielectric layer 110 on an upper surface of a wafer;
(III) covering the upper surface of the wafer with a first mask layer 501, and performing etching, so as to form a gate region gate contact (Contact/CT) 1091 at the trench gate 105 in a gate region that communicates the trench gate with the first dielectric layer 110, and at the same time, form a gate region source contact 1092 between laterally adjacent trench gates in the gate region that communicates the source end N-type implantation region 108 with the P-type bulk region 106 and form a source region source contact 1093 between laterally adjacent trench gates in a source region that communicates the source end N-type implantation region 108 with the P-type bulk region 106;
(IV) performing P-type ion implantation, so as to form a source P-type doped pillar (P-pillar/PPL) 1032 in the N-type epitaxial layer 102 below each of the gate region source contact 1092 and the source region source contact 1093, referring to FIG. 4, where the source P-type doped pillar 1032 is used to assist in the depletion of a drift region;
(V) removing the first mask layer 501, performing a metal process for forming contacts, filling each contact with metal tungsten, referring to FIG. 5;
(VI) performing metal layer deposition to form a top metal layer 111 on the upper surface of the wafer;
(VII) covering the top metal layer 111 with a second mask layer 502, and performing etching, so as to remove the second mask layer 502 and the top metal layer 111 above the source region source contact 1093 and the trench gate of the source region, retain the second mask layer 502 and the top metal layer 111 above the trench gate of the gate region, and retain the second mask layer 502 and the top metal layer 111 above the gate region source contact 1092, referring to FIG. 6;
(VIII) removing the second mask layer 502, referring to FIG. 7;
(IX) depositing a second dielectric layer 113 on the upper surface of the wafer, referring to FIG. 8.

In the existing method for manufacturing an N-type superjunction trench gate MOSFET, in order to reduce the number of photomask layers, two mask layers, the contact (CT) and the doped pillar (PPL), are merged into one mask layer in a layout design, referring to FIG. 9.

In the existing method for manufacturing an N-type superjunction trench gate MOSFET, all contacts (CTs) and doped pillars (PPLs) of the gate region are covered by the gate region metal layer GATE M1. Coated by a gate dielectric (the first dielectric layer 110), the contacts (CTs) and the doped pillars (PPLs) of the gate region are disconnected from contacts (CTs) and doped pillars (PPLs) in the vicinity thereof, e.g., referring to FIG. 8, the gate region gate contact 1091 in a leftmost gate trench and a gate P-type doped pillar (P-pillar/PPL) 1031 below the gate trench, and the rightmost gate region source contact 1092 and the source P-type doped pillar (P-pillar/PPL) 1032 therebelow. However, this manufacturing method may result in the metal tungsten in the source region source contact 1093 of the source region covered with no top metal layer M1, i.e., exposing the source region source contact 1093 of a region where the source-bulk region metal layer SOURCE-BULK M1 is located. Referring to FIG. 8, the source region source contact 1093 in the middle is exposed, and the metal tungsten in the contact has a risk of being connected to other conductors in short circuits.

### BRIEF SUMMARY

The technical problem to be solved by the present application is to provide a method for manufacturing a superjunction trench gate MOSFET, which not only can reduce mask layers to reduce manufacturing costs, but also can avoid short circuits caused by connection of exposed metal tungsten in a source region source contact to other conductors, thereby reducing the process risk.

To solve the above technical problem, the method for manufacturing a superjunction trench gate MOSFET provided by the present application includes the following steps:
S1, forming a trench gate 105 in a first-type epitaxial layer 102 on an upper side of a first-type substrate 101, forming a second-type bulk region 106 in a surface layer of the first-type epitaxial layer 102, and performing first-type heavy doping implantation in a surface layer of the second-type bulk region 106 to form a source end first-type implantation region 108, wherein a first type is an N type and a second type is a P type, or the first type is a P type and the second type is an N type;
S2, forming a first dielectric layer 110 on an upper surface of a wafer;
S3, covering the upper surface of the wafer with a first mask layer 501, and performing etching, so as to form a gate region gate contact 1091 that communicates the trench gate with the first dielectric layer 110 at the trench gate 105 in a gate region, and at the same time, form a gate region source contact 1092 that communicates the source end first-type implantation region 108 with the second-type bulk region 106 between laterally adjacent trench gates in the gate region and form a source region source contact 1093 that communicates the source end first-type implantation region 108 with the second-type bulk region 106 between laterally adjacent trench gates in a source region;
S4, performing second-type ion implantation, so as to form a source second-type doped pillar 1032 in the first-type epitaxial layer 102 below each of the gate region source contact 1092 and the source region source contact 1093, and at the same time, form a gate second-type doped pillar 1031 in the first-type epitaxial layer 102 below the gate region gate contact 1091;
S5, removing the first mask layer 501, performing a contact metal process, and filling each contact with metal tungsten;
S6, performing metal layer deposition to form a top metal layer 111 on the upper surface of the wafer;
S7, covering the top metal layer 111 with a second mask layer 502, and performing etching, so as to remove the second mask layer 502 and the top metal layer 111 above the source region source contact 1093 and the trench gate of the source region, retain the second mask layer 502 and the top metal layer 111 above the trench gate of the gate region, and retain the second mask layer 502 and the top metal layer 111 above the gate region source contact 1092;
S8, performing etching to remove the metal tungsten in the source region source contact 1093;
S9, removing the second mask layer 502 and depositing a second dielectric layer 113 on the upper surface of the wafer.

In some examples, in step S8, a wet etching process is used to etch off the metal tungsten in the source region source contact 1093.

In some examples, in step S6, the metal layer deposition is performed to form the top metal layer 111 on the upper surface of the wafer and form a bottom metal layer 112 that serves as a drain end metal layer on a lower surface of the wafer.

In some examples, a lower end of the source second-type doped pillar 1032 is lower than a lower end of a gate trench.

In some examples, in step S5, the contact metal process includes:
S51, depositing a Ti/TiN layer;
S52, performing annealing to alloy the Ti/TiN layer with silicon;
S53, depositing metal tungsten;
S54, performing etch back or CMP to remove the tungsten and the Ti/TiN layer on the surface of the wafer, leaving a tungsten plug to fill the contact.

In some examples, in step S8, a wet etching process is used to etch off a Ti/TiN/tungsten metal stack layer in the source region source contact 1093.

In some examples, step S1 includes the following steps:
S11, forming the N-type epitaxial layer 102 on the N-type substrate 101;
S12, performing P-type ion implantation in the surface layer of the N-type epitaxial layer 102 to form the P-type bulk region 106;
S13, performing photolithographic etching to form a gate region gate trench and a source region gate trench in the N-type epitaxial layer 102;
S14, sequentially forming a trench gate dielectric layer 104 and a trench gate polysilicon layer in both the gate region gate trench and the source region gate trench, so as to form the trench gate 105;
S15, performing N-type heavy doping implantation in the surface layer of the P-type bulk region 106 to form the source end N-type implantation region 108.

In some examples, a doping concentration of the N-type substrate 101 is 2.5e13-1e14 cm⁻³.

In some examples, a doping concentration of the N-type epitaxial layer 102 is 5e15-1e17 cm⁻³.

In some examples, the second mask layer 502 is a hard mask material;
the first mask layer 501 is a photoresist.

In the method for manufacturing a superjunction trench gate MOSFET of the present application, after the top metal layer 111 is fully etched off using a photomask for etching the top metal layer 111 and the second mask layer 502, the second mask layer 502 is not removed, etching continues on the exposed metal tungsten in the source region source contact 1093 to fully etch off the exposed metal tungsten (or the metal stack layer) in the source region source contact 1093, followed by removing the second mask layer 502, and then the second dielectric layer 113 is formed, not only reducing mask layers to reduce manufacturing costs, but also avoiding short circuits caused by connection of the exposed metal tungsten in the source region source contact 1093 to other conductors. This method can avoid the exposure of the metal tungsten in the case of saving one mask layer, and the process risk is reduced.

### BRIEF DESCRIPTION OF THE DRAWINGS

In order to explain the technical solutions of the present application more clearly, the drawings required by the present application is briefly described below. It is obvious that the drawings described below are merely some embodiments of the present application, and those skilled in the art could also obtain other drawings on the basis of these drawings without the practice of inventive effort.

FIG. 1 is a schematic diagram of a longitudinal section of an existing superjunction trench gate MOSFET;

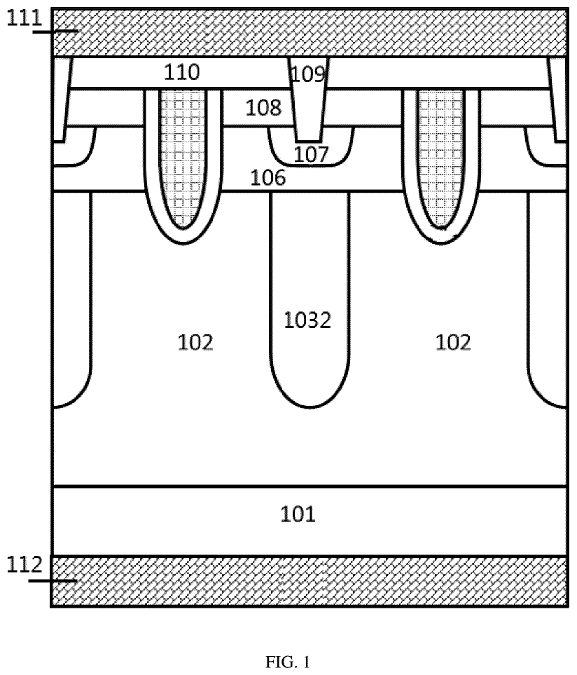

FIG. 2 illustrates a layout structure of the existing superjunction trench gate MOSFET with an additional mask layer introduced thereinto;

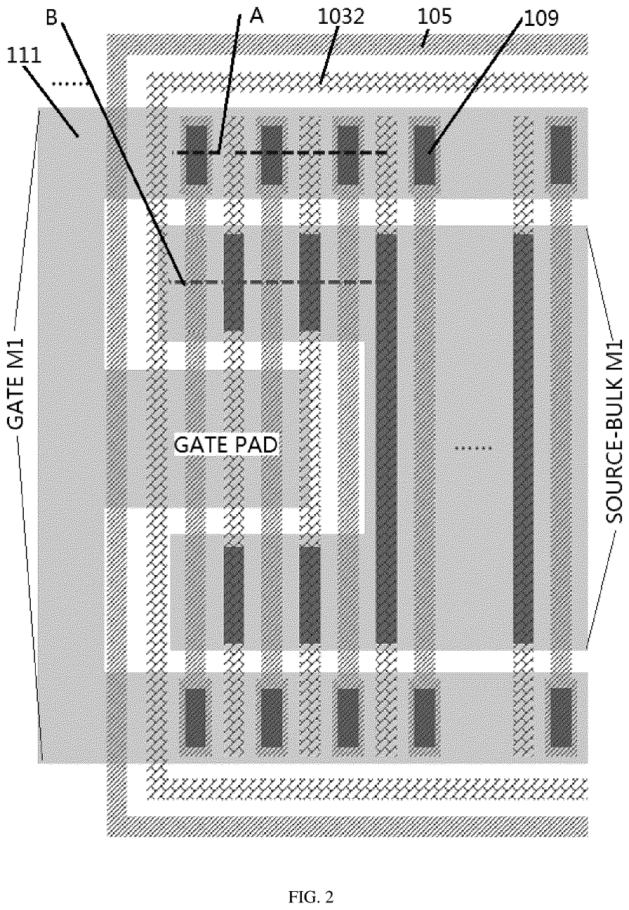

FIG. 3 is a schematic diagram of a longitudinal section of along a cut line A of the superjunction trench gate MOSFET of FIG. 2;

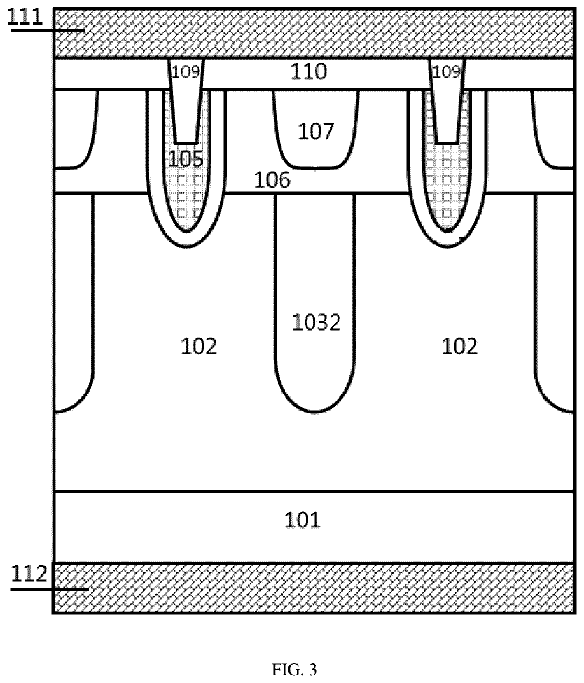

FIG. 4 is a schematic diagram of a longitudinal section resulting from forming a source second-type doped pillar according to a method for manufacturing a superjunction trench gate MOSFET;

FIG. 5 is a schematic diagram of a longitudinal section resulting from filling a contact with metal tungsten according to the method for manufacturing a superjunction trench gate MOSFET;

FIG. 6 is a schematic diagram of a longitudinal section resulting from removing a mask layer and a metal layer above a source region source contact and a trench gate of a source region according to the method for manufacturing a superjunction trench gate MOSFET;

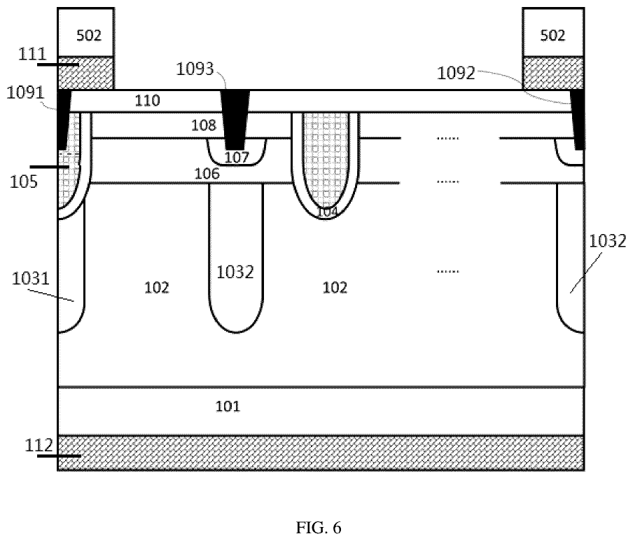

FIG. 7 is a schematic diagram of a longitudinal section resulting from removing a second mask layer directly according to an existing method for manufacturing a superjunction trench gate MOSFET;

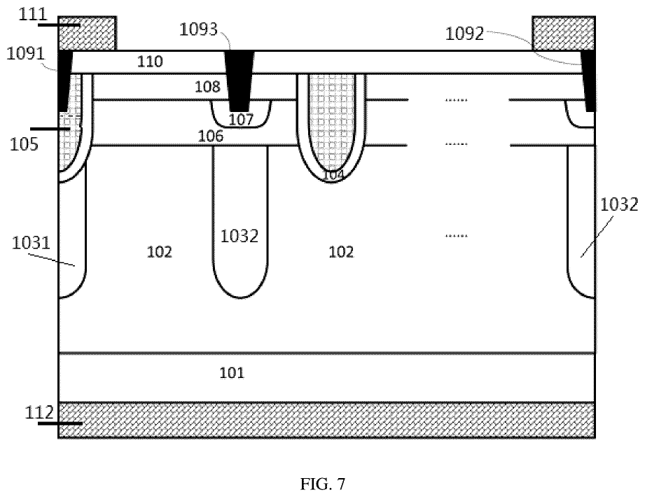

FIG. 8 is a schematic diagram of a longitudinal section resulting from depositing a second dielectric layer on an upper surface of a wafer according to the existing method for manufacturing a superjunction trench gate MOSFET;

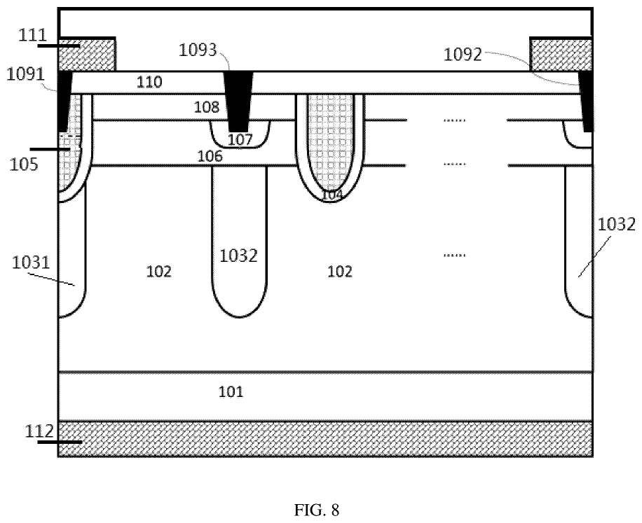

FIG. 9 illustrates a new layout structure of a superjunction trench gate MOSFET with an additional mask layer introduced thereinto;

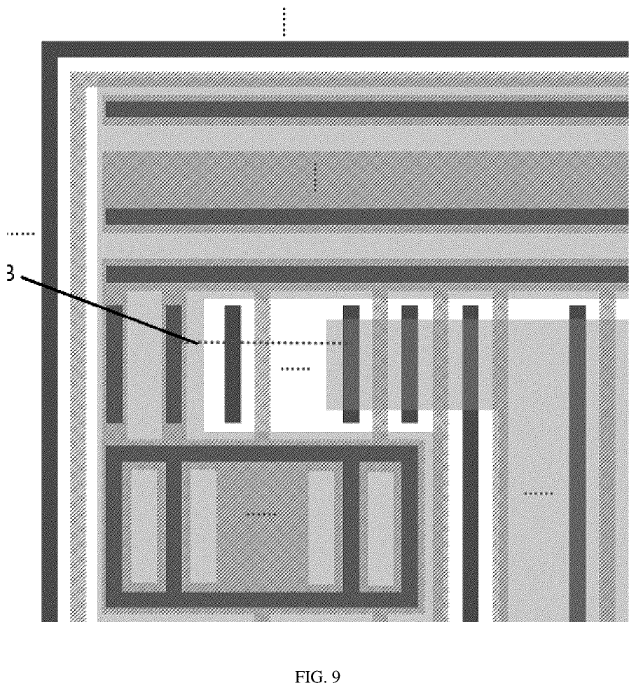

FIG. 10 is a schematic diagram of a longitudinal section resulting from etching off metal tungsten in the source region source contact according to the method for manufacturing a superjunction trench gate MOSFET of the present application;

FIG. 11 is a schematic diagram of a longitudinal section resulting from depositing the second dielectric layer on the upper surface of the wafer according to the method for manufacturing a superjunction trench gate MOSFET of the present application.

### DETAILED DESCRIPTION OF THE DISCLOSURE

The technical solutions in the embodiments of the present application will be clearly and completely described below in conjunction with the drawings. Obviously, the described embodiments are only part of the embodiments of the present application, rather than all of the embodiments. Based on the embodiments in the present application, all other embodiments obtained by those skilled in the art without the practice of inventive effort shall fall into the protection scope of the present application.

The term “first” or “second”, and like phrases used in the present application do not indicate any order, quantity, or importance, but are used only to distinguish different constituent parts. The term “include” or “comprise”, and like phrases mean that the components or objects in front of these terms cover components or objects listed after the terms and equivalents thereof, without excluding other components or objects. The term “connection” or “coupling”, and like phrases are not limited to physical or mechanical connections, but may include electrical connections, whether direct or indirect. The terms “up”, “down”, “left”, and “right”, etc. are only used to represent relative positional relationships, which may change accordingly after absolute positions of the described objects are changed.

It should be noted that the embodiments or features in the embodiments of the present application may be combined with each other in the case of no conflicts.

### Embodiment I

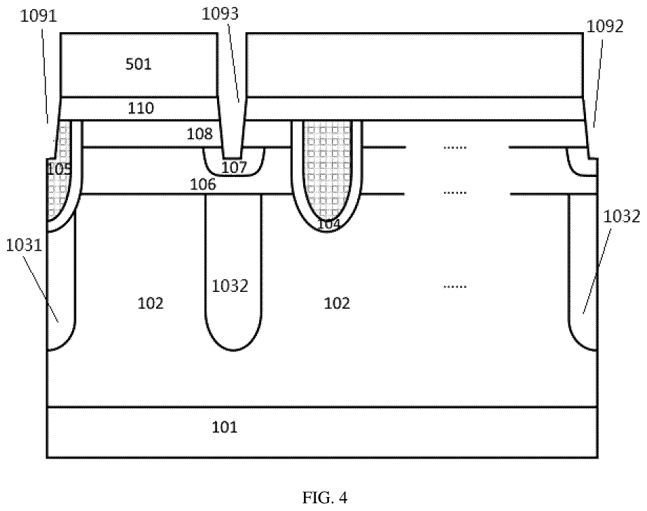

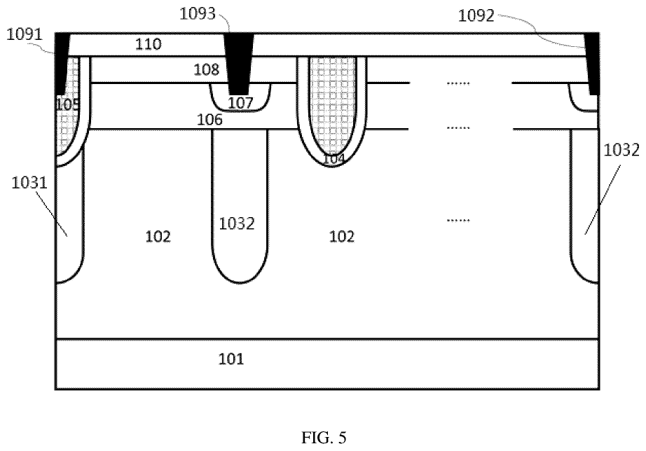

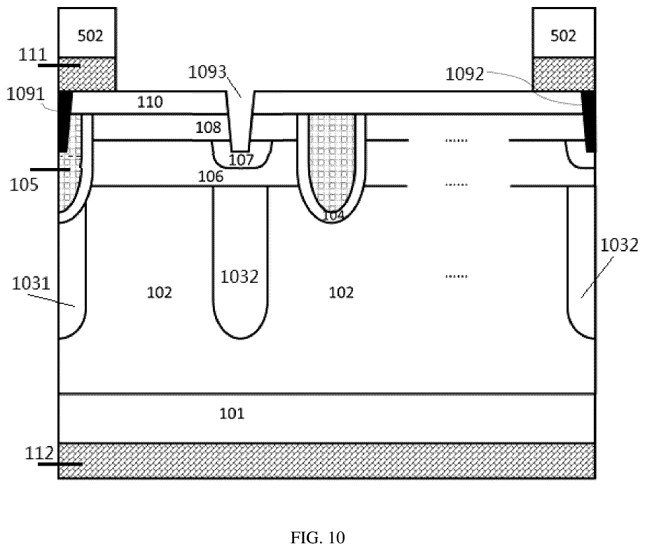

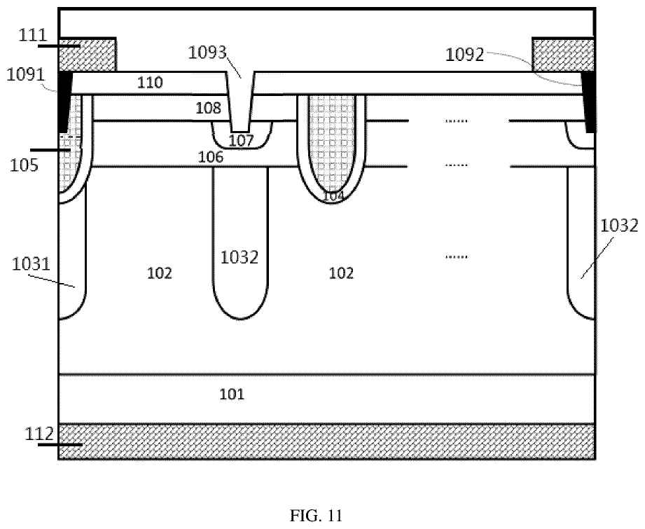

A method for manufacturing superjunction trench gate MOSFET includes the following steps:
S1, forming a trench gate 105 in a first-type epitaxial layer 102 on an upper side of a first-type substrate 101, forming a second-type bulk region 106 in a surface layer of the first-type epitaxial layer 102, and performing first-type heavy doping implantation in a surface layer of the second-type bulk region 106 to form a source end first-type implantation region 108, wherein a first type is an N type and a second type is a P type, or the first type is a P type and the second type is an N type;
S2, forming a first dielectric layer 110 on an upper surface of a wafer;
S3, covering the upper surface of the wafer with a first mask layer 501, and performing etching, so as to form a gate region gate contact 1091 that communicates the trench gate with the first dielectric layer 110 at the trench gate 105 in a gate region, and at the same time, form a gate region source contact 1092 that communicates the source end first-type implantation region 108 with the second-type bulk region 106 between laterally adjacent trench gates in the gate region and form a source region source contact 1093 that communicates the source end first-type implantation region 108 with the second-type bulk region 106 between laterally adjacent trench gates in a source region;
S4, performing second-type ion implantation, so as to form a source second-type doped pillar 1032 in the first-type epitaxial layer 102 below each of the gate region source contact 1092 and the source region source contact 1093, and at the same time, form a gate second-type doped pillar 1031 in the first-type epitaxial layer 102 below the gate region gate contact 1091, as shown in FIG. 4. The source second-type doped pillar 1032 is used to assist in the depletion of the drift region;
S5, removing the first mask layer 501, performing a contact metal process, and filling each contact with metal tungsten, as shown in FIG. 5;
S6, performing metal layer deposition to form a top metal layer 111 on the upper surface of the wafer;
S7, covering the top metal layer 111 with a second mask layer 502, and performing etching, so as to remove the second mask layer 502 and the top metal layer 111 above the source region source contact 1093 and the trench gate of the source region, retain the second mask layer 502 and the top metal layer 111 above the trench gate of the gate region, and retain the second mask layer 502 and the top metal layer 111 above the gate region source contact 1092, as shown in FIG. 10;
S8, performing etching to remove the metal tungsten in the source region source contact 1093;
S9, removing the second mask layer 502 and depositing a second dielectric layer 113 on the upper surface of the wafer, as shown in FIG. 11;

In the method for manufacturing a superjunction trench gate MOSFET of Embodiment I, after the first dielectric layer 110 is formed, the first mask layer 501 is applied and subjected to development, the first dielectric layer 110 is etched, followed by etching polysilicon/silicon at the same time, and the ion implantation is performed using the same photomask and the first mask layer 501, so as to form the source second-type doped pillar 1032 in the first-type epitaxial layer 102 below the gate region source contact 1092 and the source region source contact 1093. All contacts (CTs) and doped pillars (PPLs) of the gate region are covered by the gate region metal layer GATE M1. Coated by a gate dielectric (the first dielectric layer 110), the contacts (CTs) and the doped pillars (PPLs) of the gate region are disconnected from contacts (CTs) and doped pillars (PPLs) in the vicinity thereof. Moreover, the source region source contact 1093 is free of the metal tungsten and filled with the second dielectric layer 113, referring to FIG. 11. In the method for manufacturing a superjunction trench gate MOSFET, after the top metal layer 111 is fully etched off using a photomask for etching the top metal layer 111 and the second mask layer 502, the second mask layer 502 is not removed, etching continues on the exposed metal tungsten in the source region source contact 1093 to fully etch off the exposed metal tungsten (or the metal stack layer) in the source region source contact 1093, followed by removing the second mask layer 502, and then the second dielectric layer 113 is formed, not only reducing mask layers to reduce manufacturing costs, but also avoiding short circuits caused by connection of the exposed metal tungsten in the source region source contact 1093 to other conductors. This method can avoid the exposure of the metal tungsten in the case of saving one mask layer, and the process risk is reduced.

### Embodiment II

Based on the method for manufacturing a superjunction trench gate MOSFET of Embodiment I, in step S8, a wet etching process is used to etch off the metal tungsten in the source region source contact 1093 that is not covered by the second mask layer 502, so as to avoid the exposure of the metal tungsten.

In some examples, in step S6, the metal layer deposition is performed to form the top metal layer 111 on the upper surface of the wafer and form a bottom metal layer 112 that serves as a drain end metal layer on a lower surface of the wafer.

In some examples, a lower end of the source second-type doped pillar 1032 is lower than a lower end of a gate trench.

### Embodiment III

Based on the method for manufacturing a superjunction trench gate MOSFET of Embodiment I, in step S5, the contact metal process includes:
S51, depositing a Ti/TiN layer;
S52, performing annealing to alloy the Ti/TiN layer with silicon;
S53, depositing metal tungsten;
S54, performing etch back or chemical mechanical polishing (CMP) to remove the tungsten and the Ti/TiN layer on the surface of the wafer, leaving a tungsten plug to fill the contact.

In some examples, in step S8, a wet etching process is used to etch off a Ti/TiN/tungsten metal stack layer in the source region source contact 1093.

### Embodiment V

Based on the method for manufacturing a superjunction trench gate MOSFET of Embodiment I, step S1 includes the following steps:
S11, forming the N-type epitaxial layer 102 on the N-type substrate 101;
S12, performing P-type ion implantation in the surface layer of the N-type epitaxial layer 102 to form the P-type bulk region 106;
S13, performing photolithographic etching to form a gate region gate trench and a source region gate trench in the N-type epitaxial layer 102;
S14, forming, by means of a P-type ion implantation process, the gate P-type doped pillar (P-pillar/PPL) 1031 extending longitudinally in the N-type epitaxial layer below the gate region gate trench;
S15, sequentially forming a trench gate dielectric layer 104 and a trench gate polysilicon layer in both the gate region gate trench and the source region gate trench, so as to form the trench gate 105;
S16, performing N-type heavy doping implantation in the surface layer of the P-type bulk region 106 to form the source end N-type implantation region 108.

In some examples, a doping concentration of the N-type substrate 101 is 2.5e13-1e14 cm⁻³.

In some examples, a doping concentration of the N-type epitaxial layer 102 is 5e15-1e17 cm⁻³.

In some examples, the second mask layer 502 is a hard mask material or a photoresist.

In some examples, the first mask layer 501 is a photoresist or a hard mask material.

The above descriptions are merely examples of the embodiments of the present application and are not intended to limit the present application. Any modifications, equivalent substitutions, and improvements, etc. made within the spirit and principles of the present application shall be included within the protection scope of the present application.

What is claimed is:

1. A method for manufacturing a superjunction trench gate MOSFET, wherein, comprising the following steps:
S1, forming a trench gate in a first-type epitaxial layer on an upper side of a first-type substrate, forming a second-type bulk region in a surface layer of the first-type epitaxial layer, and performing first-type heavy doping implantation in a surface layer of the second-type bulk region to form a source end first-type implantation region, wherein a first type is an N type and a second type is a P type, or the first type is a P type and the second type is an N type;
S2, forming a first dielectric layer on an upper surface of a wafer;
S3, covering the upper surface of the wafer with a first mask layer, and performing etching, so as to form a gate region gate contact that communicates the trench gate with the first dielectric layer at the trench gate in a gate region, and at the same time, form a gate region source contact that communicates the source end first-type implantation region with the second-type bulk region between laterally adjacent trench gates in the gate region and form a source region source contact that communicates the source end first-type implantation region with the second-type bulk region between laterally adjacent trench gates in a source region;
S4, performing second-type ion implantation, so as to form a source second-type doped pillar in the first-type epitaxial layer below each of the gate region source contact and the source region source contact, and at the same time, form a gate second-type doped pillar in the first-type epitaxial layer below the gate region gate contact;
S5, removing the first mask layer, performing a contact metal process, and filling each contact with metal tungsten;
S6, performing metal layer deposition to form a top metal layer on the upper surface of the wafer;
S7, covering the top metal layer with a second mask layer, and performing etching, so as to remove the second mask layer and the top metal layer above the source region source contact and the trench gate of the source region, retain the second mask layer and the top metal layer above the trench gate of the gate region, and retain the second mask layer and the top metal layer above the gate region source contact;
S8, performing etching to remove the metal tungsten in the source region source contact;
S9, removing the second mask layer and depositing a second dielectric layer on the upper surface of the wafer.

2. The method for manufacturing a superjunction trench gate MOSFET according to claim 1, wherein:
in step S8, a wet etching process is used to etch off the metal tungsten in the source region source contact.

3. The method for manufacturing a superjunction trench gate MOSFET according to claim 1, wherein:
in step S6, the metal layer deposition is performed to form the top metal layer on the upper surface of the wafer and form a bottom metal layer that serves as a drain end metal layer on a lower surface of the wafer.

4. The method for manufacturing a superjunction trench gate MOSFET according to claim 1, wherein:
a lower end of the source second-type doped pillar is lower than a lower end of a gate trench.

5. The method for manufacturing a superjunction trench gate MOSFET according to claim 1, wherein:
in step S5, the contact metal process comprises:
S51, depositing a Ti/TiN layer;
S52, performing annealing to alloy the Ti/TiN layer with silicon;
S53, depositing metal tungsten; and
S54, performing etch back or CMP to remove the tungsten and the Ti/TiN layer on the surface of the wafer, leaving a tungsten plug to fill the contact.

6. The method for manufacturing a superjunction trench gate MOSFET according to claim 5, wherein:
in step S8, a wet etching process is used to etch off a Ti/TiN/tungsten metal stack layer in the source region source contact.

7. The method for manufacturing a superjunction trench gate MOSFET according to claim 4, wherein:
step S1 comprises the following steps:
S11, forming the N-type epitaxial layer on the N-type substrate;
S12, performing P-type ion implantation in the surface layer of the N-type epitaxial layer to form the P-type bulk region;
S13, performing photolithographic etching to form a gate region gate trench and a source region gate trench in the N-type epitaxial layer;
S14, sequentially forming a trench gate dielectric layer and a trench gate polysilicon layer in both the gate region gate trench and the source region gate trench, so as to form the trench gate;
S15, performing N-type heavy doping implantation in the surface layer of the P-type bulk region to form the source end N-type implantation region.

8. The method for manufacturing a superjunction trench gate MOSFET according to claim 7, wherein:
a doping concentration of the N-type substrate is 2.5e13-1e14 cm⁻³.

9. The method for manufacturing a superjunction trench gate MOSFET according to claim 7, wherein:
a doping concentration of the N-type epitaxial layer is 5e15-1e17 cm⁻³.

10. The method for manufacturing a superjunction trench gate MOSFET according to claim 1, wherein:
the second mask layer is a hard mask material; and
the first mask layer is a photoresist.
